(19) United States
(12) Patent Application Publication
(10) Pub. No.: US 2026/0065970 A1
(43) Pub. Date: Mar. 5, 2026

(54) SIGNAL PROCESSING CIRCUIT AND MEMORY

(71) Applicant: CXMT Corporation, Hefei (CN)

(72) Inventor: Yinchuan GU, Hefei (CN)

(21) Appl. No.: 19/385,165

(22) Filed: Nov. 11, 2025

Related U.S. Application Data
(63) Continuation of application No. PCT/CN2023/110860, filed on Aug. 2, 2023.

(30) Foreign Application Priority Data
Jun. 27, 2023 (CN) 202310776136.0

(51) Int. Cl. G11C 11/408; G11C 11/4076

(52) U.S. Cl. CPC G11C 11/4087; G11C 11/4076

(57) ABSTRACT

The present disclosure provides a signal processing circuit and a memory. The signal processing circuit includes a pulse widening circuit and an address decoding circuit. The pulse widening circuit is configured to widen a pulse width of an address signal through a command signal, thereby generating a widened address signal. An input terminal of the address decoding circuit is coupled to an output terminal of the pulse widening circuit for decoding the widened address signal to generate a decoded address signal.

### CROSS REFERENCES TO RELATED APPLICATIONS

The present application is a continuation application of Internation Patent Application No. PCT/CN2023/110860, filed on Aug. 2, 2023, which claims priority to Chinese Patent Application No. 202310776136.0 filed with China National Intellectual Property Administration on Jun. 27, 2023, and entitled “SIGNAL PROCESSING CIRCUIT AND MEMORY”, the content of which is incorporated herein by reference in its entirety.

### TECHNICAL FIELD

The present disclosure relates to, but is not limited to, a signal processing circuit and a memory.

### BACKGROUND

In a memory, a command signal and an address signal are needed to indicate a command operation to be performed and an address for performing the operation. For example, the command signal and the address signal are used to indicate the execution of a pre-charge command on part or all of the rows in a target memory bank (bank, BA) within a target memory bank group (bank group, BG). Before the command signal and the address signal reach the target BA of the target BG, a series of processing needs to be performed on the command signal and the address signal.

In the prior art, an address decoding circuit is provided in the memory. The address decoding circuit is configured to receive an address signal, to decode the address signal to obtain a decoded address signal. A command can then be executed on the memory based on the decoded address signal and a command signal.

However, the above solution may lead to command execution errors.

### SUMMARY

Embodiments of the present disclosure provide a signal processing circuit and a memory to reduce the command execution error rate.

In a first aspect, the embodiments of the present disclosure provide a signal processing circuit. The signal processing circuit includes:
a pulse widening circuit and an address decoding circuit.

The pulse widening circuit is configured to receive a command signal and an address signal, and to widen a pulse width of the address signal through the command signal, thereby generating a widened address signal.

An input terminal of the address decoding circuit is coupled to an output terminal of the pulse widening circuit for receiving the widened address signal, so as to decode the widened address signal and generate a decoded address signal corresponding to the address signal.

In a second aspect, the present disclosure provides a memory. The memory includes the signal processing circuit according to the first aspect.

The embodiments of the present disclosure provide a signal processing circuit and a memory. The pulse widening circuit is configured to receive a command signal and an address signal, and to widen a pulse width of the address signal through the command signal, thereby generating a widened address signal. An input terminal of the address decoding circuit is coupled to an output terminal of the pulse widening circuit for receiving the widened address signal, so as to decode the widened address signal and generate a decoded address signal corresponding to the address signal. According to the present disclosure, pulse widening can be performed on the address signal to increase the pulse width of the address signal. Pulse widening can provide more timing margins for address decoding, which helps to ensure the accuracy of command sampling and improve the success rate of command execution.

### BRIEF DESCRIPTION OF DRAWINGS

FIG. 1 is a schematic diagram of address information decoding of a memory according to the prior art;

FIG. 2 is a schematic structural diagram of a signal processing circuit according to an embodiment of the present disclosure;

FIG. 3 is a schematic diagram of the connection of an input terminal of a first flip-flop according to an embodiment of the present disclosure;

FIG. 4 is a schematic diagram of extending an address signal through a command signal according to an embodiment of the present disclosure;

FIG. 5 is a schematic diagram of another connection of the input terminal of the first flip-flop according to an embodiment of the present disclosure;

FIG. 6 is a schematic diagram of another way of extending an address signal through a command signal according to an embodiment of the present disclosure; and

FIG. 7 and FIG. 8 are schematic structural diagrams of another two signal processing circuits according to an embodiment of the present disclosure.

### DESCRIPTION OF EMBODIMENTS

The technical solutions in the embodiments of the present disclosure will be clearly and completely described below with reference to the embodiments of the present disclosure and the drawings. It is obvious that the described embodiments are only part of the embodiments of the present disclosure rather than all embodiments. All other embodiments, which are derived by those of ordinary skill in the art from the embodiments of the present disclosure without inventive efforts, are intended to fall within the scope of protection of the present disclosure.

In the specification, claims, and drawings of the present disclosure, the terms “first”, “second”, and the like are intended to distinguish between similar objects and do not necessarily indicate a specific order or sequence. It should be understood that the data used in this way can be interchanged under appropriate circumstances, so that the embodiments of the present disclosure described herein can, for example, be implemented in sequences other than those illustrated or described herein.

In addition, the terms “comprise”, “include”, “have”, “provided with”, and any variations thereof used herein are intended to cover non-exclusive inclusions. For example, a process, method, system, product, or device including a series of steps or units is not necessarily limited to those steps or units explicitly listed, but may include other steps or units not explicitly listed or inherent to the process, method, product, or device.

The embodiments of the present disclosure are applicable to a memory, which is any semiconductor device for data storage and data access. For example, the memory may be a dynamic random access memory (dynamic random accessing memory, DRAM). The DRAM may include, but is not limited to, a synchronous dynamic random access memory (synchronous dynamic random accessing memory, SDRAM). The SDRAM may include, but is not limited to, a double data rate (DDR) SDRAM from DDR 1 to DDR 6, and a low power double data rate (LPDDR) SDRAM from LPDDR 1 to LPDDR6.

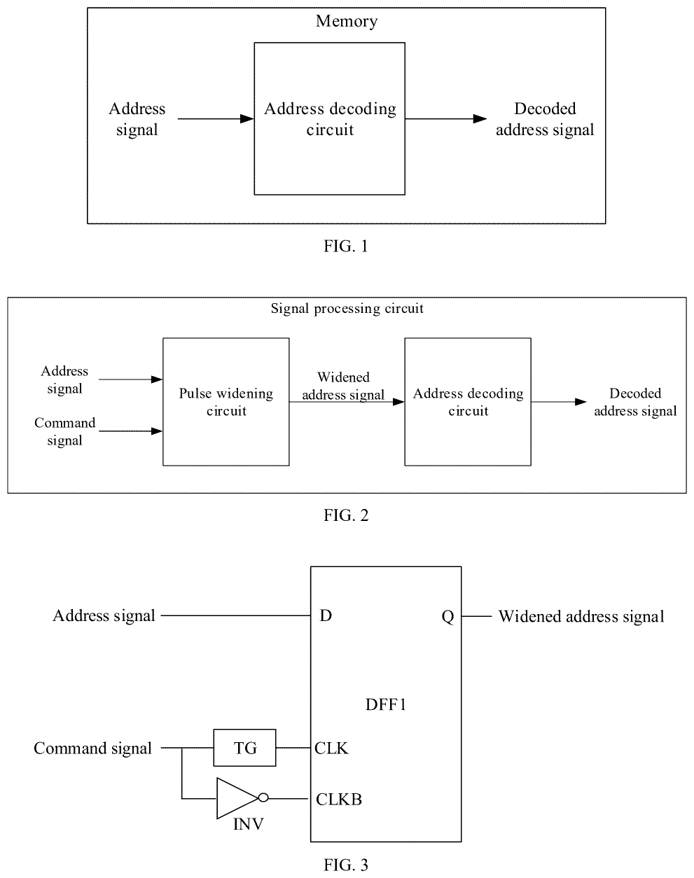

The memory can provide a data storage function and a data access function to the outside. The realization of these functions needs to rely on a command signal and an address signal. Referring to FIG. 1, the address signal needs to be decoded by an address decoding circuit provided in a memory to obtain a decoded address signal. The decoded address signal and the command signal are used together to perform a command operation.

The address signal will be transmitted over a long distance, which may cause a skew (skew) or an increase in skew among signals of a plurality of bits in the address signal. The skew among the signals of a plurality of bits refers to a time offset in pulses of the signals of a plurality of bits. A larger skew indicates a shorter pulse overlap time among the signals of a plurality of bits, and a smaller skew indicates a longer pulse overlap time among the signals of a plurality of bits.

In some scenarios, an external circuit sends a command address (CA) signal to the memory, and the CA signal carries both an external command signal and an external address signal. For example, for a pre-charge (precharge, PRE) command, the first to fifth pins of the memory receive the external PRE command signal in the CA signal, and the sixth to eleventh pins of the memory receive the address signal in the CA signal; each pin corresponds to a signal of one bit.

After receiving the external command signal, the memory processes the external command signal to obtain a command signal and processes the external address signal to obtain an address signal. Therefore, the command signal and the address signal may both be signals of a plurality of bits. For the PRE command, the address signal includes a BGBA signal of five bits.

Before long-distance transmission, the rising edges of the BGBA signal of five bits are all aligned, and the falling edges are also all aligned. The pulse overlap time among the five bits of the BGBA signal is relatively long; that is, the skew among the five bits of the signal is relatively small.

However, after long-distance transmission, the rising edges of the BGBA signal of five bits are no longer aligned, and/or the falling edges are no longer aligned. The pulse overlap time among the five bits of the BGBA signal is reduced; that is, the skew among the five bits of the signal is increased.

After the skew among the signals of a plurality of bits of the address signal increases due to the long-distance transmission, when the address signal is decoded, the pulse width of the address signal will be reduced. As a result, subsequent command sampling errors occur, leading to further command execution errors.

It should be noted that the skew among the signals of a plurality of bits in the address signal will increase with the increase of the signal transmission distance, and/or the smaller the pulse width of the address signal, the greater the influence of the skew, thereby resulting in a higher probability of command execution errors. For example, under the 1N mode, the pulse width of the command signal and the pulse width of the address signal are both 1TCK (one clock cycle), and the sampling period of both is 1TCK. Under the 2N mode, the pulse width of the command signal and the pulse width of the address signal are both 2TCK, and the sampling period of both is 2TCK. Therefore, compared with the 2N mode, the 1N mode has a smaller pulse width, and a command execution error caused by the skew is more likely to occur.

In order to solve the above technical problem, in the embodiments of the present disclosure, pulse widening may be performed on the address signal to increase the pulse width of the address signal. When the address signal after pulse widening is transmitted over a long distance, even if the pulse overlap time among signals of different bits is reduced due to the skew, the reduced pulse overlap time is still sufficient to ensure correct command sampling. That is, the pulse widening can provide more pulse width margin for the address decoding, and even if the address decoding reduces the pulse width, the command sampling accuracy can still be guaranteed. In addition to ensuring the success rate of command execution in low-frequency scenarios, the success rate of command execution can also be improved in high-frequency scenarios.

In the embodiments of the present disclosure, under the 1N mode with a smaller pulse width, the accuracy of command sampling and the success rate of command execution can be further improved.

It can be understood that the coupling involved in the embodiments of the present disclosure may be a direct connection or an indirect connection. The direct connection means that two circuits are connected only through a circuit connection line. The indirect connection means that both circuits are connected to another circuit, so as to realize the connection between the two circuits through the another circuit.

FIG. 2 is a schematic structural diagram of a signal processing circuit according to an embodiment of the present disclosure. The signal processing circuit may be provided in a memory. Referring to FIG. 2, the signal processing circuit includes a pulse widening circuit and an address decoding circuit.

The pulse widening circuit is configured to receive a command signal and an address signal, and to widen a pulse width of the address signal through the command signal, thereby generating a widened address signal.

An input terminal of the address decoding circuit is coupled to an output terminal of the pulse widening circuit for receiving the widened address signal, so as to decode the widened address signal and generate a decoded address signal corresponding to the address signal.

In the embodiments of the present disclosure, the command signal includes, but is not limited to, at least one of the following signals: a PRE command signal, a refresh (REF) command signal, or a refresh management (RFM) command signal.

The PRE command signal is used to precharge any row in any BA of any BG in the memory, to pull up voltages of both a bit line (BL) and a complementary bit line (BLB) in the row to a reference voltage. The PRE command signal corresponds to an address signal, and the address signal includes a BG address signal, a BA address signal, and a row address signal.

The REF command signal is used to perform a data refresh on the memory and includes a specified memory bank refresh (refresh same bank, REFsb) command signal, an all memory bank refresh (refresh all bank, REFab) command signal, a self refresh (self refresh, SREF) command signal, and an auto refresh (auto refresh, AREF) command signal.

The REFsb command signal is used to perform a data refresh on a specified BA of all BGs in the memory. Therefore, no BG address signal is carried, but a BA address signal is carried.

The REFab command signal is used to perform a data refresh on all BAs of all BGs in the memory. Therefore, no BG address signal or BA address signal is carried. The RFM command signal is used to perform data refresh management on the memory and is divided into two types: a specified memory bank refresh management (refresh management same bank, RFMsb) command signal and an all memory bank refresh management (refresh management all bank, RFMab) command signal. Similarly, the RFMsb command signal is used to perform data refresh management on a specified BA of all BGs in the memory. Therefore, no BG address signal is carried, but a BA address signal is carried. The RFMab command signal is used to perform data refresh management on all BAs of all BGs in the memory. Therefore, no BG address signal or BA address signal is carried.

In addition, the address signal includes at least one of the following signals: a BG address signal and a BA address signal. The BG address signal may be a multi-bit BG address signal, and the BA address signal may also be a multi-bit BA address signal. For some command signals, the corresponding address signals thereof include not only the BG address signal but also the BA address signal. The PRE command signal is such an example. For some command signals, the corresponding address signals thereof include only a BA address signal. The REFsb command signal and the RFMsb command signal are such examples.

In summary, the embodiments of the present disclosure are applicable to command execution scenarios involving command signals carrying an address signal. In such scenarios, pulse widening can be performed on the address signal to obtain a widened address signal, so that the widened address signal is used to execute commands together with the command signals. In a command execution scenario involving a command signal that does not carry an address signal, there is no pulse in the address signal. Therefore, the results of performing and not performing pulse widening on the address signal are the same. However, for the sake of circuit uniformity, a pulse widening circuit is provided before each of the address decoding circuits.

It can be understood that when the pulse width of the address signal is widened through the command signal, the pulse width of the widened address signal obtained by widening is associated with the frequency of the command signal. That is, the pulse width of the widened address signal is the same as the time interval between two adjacent pulses of the command signal. For example, when the command signal is sent once every two TCKs, the pulse width of the address signal may be widened to two TCKs; when the command signal is sent once every five TCKs, the pulse width of the address signal may be widened to five TCKs. The process of generating the widened address signal can be divided into two situations.

In the first situation, when a rising edge of the command signal appears and the rising edge samples an active level of the widened address signal, a pulse of the widened address signal begins; when a next rising edge of the command signal appears and the rising edge fails to sample the active level of the widened address signal, the pulse of the widened address signal ends.

In the second situation, when a falling edge of the command signal appears and the falling edge samples the active level of the widened address signal, a pulse of the widened address signal begins; when a next falling edge of the command signal appears and the falling edge fails to sample the active level of the widened address signal, the pulse of the widened address signal ends.

In some embodiments, the pulse widening circuit may include a first flip-flop, and the first flip-flop may be any type of flip-flop, for example, a D-type flip-flop (D flip-flop, DFF). Therefore, in the embodiments of the present disclosure, the pulse widening of the address signal can be realized by a simple flip-flop, and the complexity of the circuit can be reduced as much as possible. The first flip-flop has two clock input terminals: an in-phase clock input terminal and an inverted clock input terminal. A phase of a signal received by the in-phase clock input terminal is opposite to a phase of a signal received by the inverted clock input terminal. The in-phase clock input terminal is configured to perform data sampling through the rising edge of the received signal; the inverted clock input terminal is configured to perform data sampling through the falling edge of the received signal.

In the embodiments of the present disclosure, the in-phase clock input terminal of the first flip-flop is configured to receive the widening control signal; the inverted clock input terminal of the first flip-flop is configured to receive an inverted signal of the widening control signal.

The widening control signal may be the command signal or an inverted signal of the command signal. When the widening control signal received by the in-phase clock input terminal of the first flip-flop is the command signal, the inverted signal of the widening control signal received by the inverted clock input terminal of the first flip-flop is the inverted signal of the command signal. When the widening control signal received by the in-phase clock input terminal of the first flip-flop is an inverted signal of the command signal, the inverted signal of the widening control signal received by the inverted clock input terminal of the first flip-flop is the command signal.

In addition, referring to FIG. 3 or FIG. 5, the first flip-flop DFF1 is further provided with a data input terminal D for receiving an address signal. Therefore, the first flip-flop DFF1 may widen the pulse width of the address signal under the control of the widening control signal, generate the widened address signal, and output the widened address signal through an output terminal Q.

In order to obtain an inverted signal of the command signal, in addition to the first flip-flop, the signal processing circuit according to the embodiments of the present disclosure may further include an inverter. In order to enable the command signal and the inverted signal of the command signal to arrive at the first flip-flop at the same time, a transfer gate (transfer gate, TG) may be further provided for transmitting an input signal. The duration required by the transfer gate to transmit the input signal is the same as the duration required by the inverter to perform phase inversion processing on the input signal.

When the widening control signal is the command signal, referring to FIG. 3, the input terminal of the inverter INV is configured to receive the command signal, and the output terminal of the inverter INV is coupled to the inverted clock input terminal CLKB of the first flip-flop DFF1 for outputting an inverted signal of the command signal to the first flip-flop DFF1. In this case, the input terminal of the transfer gate TG is configured to receive the command signal, and the output terminal of the transfer gate TG is coupled to the in-phase clock input terminal CLK of the first flip-flop DFF1 for outputting the command signal to the first flip-flop DFF1 as the widening control signal.

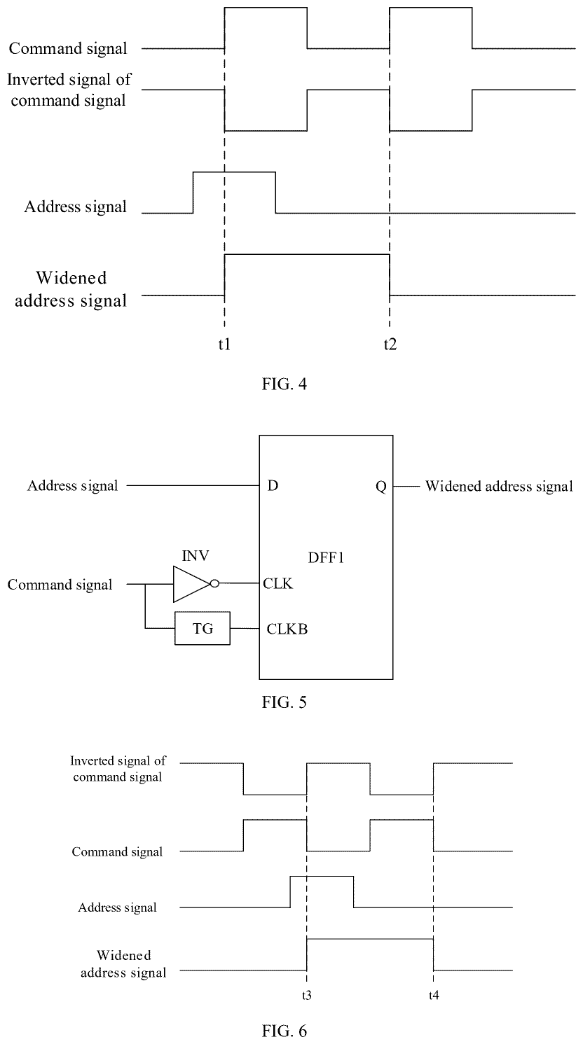

Based on the circuit shown in FIG. 3, FIG. 4 is a schematic diagram of extending an address signal through a command signal according to an embodiment of the present disclosure.

Referring to FIG. 3, since the command signal is inputted to the in-phase clock input terminal CLK of the first flip-flop DFF1, the command signal may widen the pulse of the address signal through the rising edge. Referring to FIG. 4, when a rising edge appears in the command signal at moment t1, the first flip-flop DFF1 samples the address signal to output a high-level widened address signal. When the next rising edge appears in the command signal at moment t2, the first flip-flop DFF1 samples the address signal to output a low-level widened address signal.

Referring to FIG. 3, since the inverted signal of the command signal is inputted to the inverted clock input terminal CLKB of the first flip-flop DFF1, the inverted signal of the command signal may also widen the pulse of the address signal through the falling edge. Referring to FIG. 4, when a falling edge appears in the inverted signal of the command signal at moment t1, the first flip-flop DFF1 samples the address signal to output a high-level widened address signal. When the next falling edge appears in the inverted signal of the command signal at moment t2, the first flip-flop DFF1 samples the address signal to output a low-level widened address signal.

It can be seen from FIG. 4 that the first flip-flop can achieve the pulse widening of the address signal through either the command signal or the inverted signal of the command signal, so that the pulse width of the widened address signal is the same as the time interval between two adjacent rising edges of the command signal, or is the same as the time interval between two adjacent falling edges of the inverted signal of the command signal.

When the widening control signal is an inverted signal of the command signal, referring to FIG. 5, the input terminal of the inverter INV is configured to receive the command signal, and the output terminal of the inverter INV is coupled to the in-phase clock input terminal CLK of the first flip-flop DFF1 for transmitting the inverted signal of the command signal to the first flip-flop DFF1 as the widening control signal. In this case, the input terminal of the transfer gate TG is configured to receive the command signal, and the output terminal of the transfer gate TG is coupled to the inverted clock input terminal CLKB of the first flip-flop DFF1 for transmitting the command signal to the first flip-flop DFF1.

Based on the circuit shown in FIG. 5, FIG. 6 is a schematic diagram of extending an address signal through a command signal according to an embodiment of the present disclosure.

Referring to FIG. 5, since the inverted signal of the command signal is inputted to the in-phase clock input terminal CLK of the first flip-flop DFF1, the inverted signal of the command signal may widen the pulse of the address signal through the rising edge. Referring to FIG. 6, when a rising edge appears in the inverted signal of the command signal at moment t3, the first flip-flop DFF1 samples the address signal to output a high-level widened address signal. When the next rising edge of the inverted signal appears in the command signal at moment t4, the first flip-flop DFF1 samples the address signal to output a low-level widened address signal.

Referring to FIG. 5, since the command signal is inputted to the inverted clock input terminal CLKB of the first flip-flop DFF1, the command signal may also widen the pulse of the address signal through the falling edge. Referring to FIG. 6, when a falling edge appears in the command signal at moment t3, the first flip-flop DFF1 samples the address signal to output a high-level widened address signal. When the next falling edge appears in the command signal at moment t4, the first flip-flop DFF1 samples the address signal to output a low-level widened address signal.

It can be seen from FIG. 6 that the first flip-flop can achieve the pulse widening of the address signal through either the inverted signal of the command signal or the command signal, so that the pulse width of the widened address signal is the same as the time interval between two adjacent rising edges of the inverted signal of the command signal, or is the same as the time interval between two adjacent falling edges of the command signal.

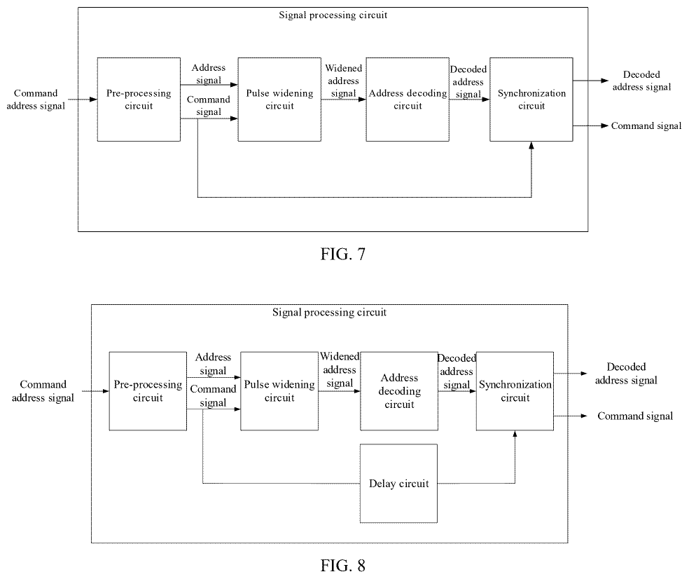

In some embodiments, referring to FIG. 7 or FIG. 8, the signal processing circuit further includes a pre-processing circuit. The pre-processing circuit is provided with a first output terminal and a second output terminal. A first output terminal of the pre-processing circuit is coupled to an input terminal of the pulse widening circuit, the input terminal being configured to receive the command signal, and a second output terminal of the pre-processing circuit is coupled to an input terminal of the pulse widening circuit, the input terminal being configured to receive the address signal. The pre-processing circuit is configured to receive a command address signal (CA signal) sent by an external circuit, to decode and amplify the CA signal to obtain a command signal and an address signal. In this way, the pre-processing circuit can output the command signal to the pulse widening circuit via the first output terminal, and output the address signal to the pulse widening circuit via the second output terminal.

Specifically, the CA signal includes a plurality of bit signals. Some of the bit signals may be referred to as external command signals, and the other bit signals may be referred to as external address signals. The pre-processing circuit is provided with a plurality of input terminals, which are configured to respectively receive an external command signal and an external address signal, so as to decode and amplify the external command signal as a command signal and amplify the external address signal as an address signal. The decoding herein is a conventional decoding operation, which may be implemented by a conventional decoder. For example, a 5-bit signal may be decoded into a 32-bit signal.

The amplification may be understood as performing amplitude amplification on a received signal to obtain a full swing signal.

In the embodiments of the present disclosure, the CA signal can be amplified by the pre-processing circuit. In this way, an internal processing error caused by signal attenuation can be avoided, which helps to further improve command execution accuracy.

In some embodiments, referring to FIG. 7, the signal processing circuit may further include a synchronization circuit. Two input terminals of the synchronization circuit are respectively coupled to the output terminal of the address decoding circuit and the first output terminal of the pre-processing circuit for synchronizing the decoded address signal and the command signal. The synchronization herein may be understood as establishing correspondence between the decoded address signal and the command signal that are separately transmitted before arriving at the synchronization circuit, so that the subsequent processing circuit of the memory can make the decoded address signal and the command signal correspond to and combine with each other. The decoded address signal is used to indicate an address with respect to which a corresponding command signal is executed. After performing synchronization by the synchronization circuit, it can be ensured that the correspondence between the address decoding signal and the command signal is accurate, which helps to further improve command execution accuracy.

The synchronization circuit may also include a second flip-flop. The data input terminal of the second flip-flop is coupled to the output terminal of the address decoding circuit to receive the decoded address signal outputted by the address decoding circuit. A clock input terminal of the second flip-flop is coupled to the first output terminal of the pre-processing circuit.

The second flip-flop may also be a DFF. The clock input terminal of the second flip-flop may be an in-phase clock input terminal of the second flip-flop or an inverted clock input terminal of the second flip-flop.

It can be seen from FIG. 7 that the input terminal of the synchronization circuit is directly connected to the first output terminal of the pre-processing circuit. However, in the embodiments of the present disclosure, a pulse widening circuit and an address decoding circuit are introduced. When the pre-processing circuit outputs the address signal and the command signal simultaneously, the delay introduced by the pulse widening circuit and the address decoding circuit may cause the time when the command signal arrives at the synchronization circuit to be earlier than the time when the decoded address signal arrives at the synchronization circuit. In such a case, the synchronization accuracy of the synchronization circuit may be poor.

To solve the above problem, referring to FIG. 8, the signal processing circuit further includes a delay circuit. An input terminal of the delay circuit is coupled to the first output terminal of the pre-processing circuit. The first output terminal is the output terminal of the pre-processing circuit for outputting the command signal. In this way, the pre-processing circuit can output the command signal to the delay circuit.

An output terminal of the delay circuit is coupled to the input terminal of the synchronization circuit for outputting the command signal after being delayed to the synchronization circuit, so as to match delays (referred to as the first delay) introduced by the pulse widening circuit and the address decoding circuit. The first delay is the sum of the delay introduced by the pulse widening circuit and the delay introduced by the address decoding circuit.

The delay circuit includes an even number of inverters connected in series. In this way, it can be ensured that the output signal of the delay circuit is in phase with the input signal of the delay circuit. For example, the number of inverters included in the delay circuit may be determined based on the first delay, so that a second delay of the delay circuit is as close as possible to the first delay. Ideally, the first delay and the second delay are the same. Therefore, the number of inverters of the delay circuit may be obtained by dividing the first delay by the delay of one inverter and rounding the result to the nearest integer.

In summary, in the embodiments of the present disclosure, on the basis that the pre-processing circuit outputs the command signal and the address signal simultaneously, the delay circuit shown in FIG. 8 makes the decoded address signal and the command signal reach the synchronization circuit at the same time as much as possible. Therefore, the synchronization accuracy of the decoded address signal and the delay signal by the synchronization circuit can be improved.

In some embodiments, a post-processing circuit may be further coupled after the synchronization circuit. The post-processing circuit may include an even number of inverters connected in series, and is configured to perform wave regulation or delay matching on the command signal and the widened address signal outputted by the synchronization circuit before performing the command operation.

It should be noted that the signal processing circuit according to the embodiments of the present disclosure is configured to process each bit of the address signal. If the address signal has a plurality of bit signals, each bit signal corresponds to one of the signal processing circuits mentioned above. For example, when the address signal is a BGBA signal of five bits, five of the signal processing circuits mentioned above are required to perform the above processing on the five bits of the BGBA signal, respectively.

The embodiments of the present disclosure further provide a memory. The memory includes the signal processing circuit as described above.

For the detailed description of the memory, reference may be made to the detailed description of the foregoing signal processing circuit, and the detailed description will not be repeated here.

It should be noted in conclusion: the above embodiments are only used to illustrate the technical solutions of the present disclosure, and are not intended to limit them. Although the present disclosure has been described in detail with reference to the foregoing embodiments, those of ordinary skill in the art should understand that modifications can still be made to the technical solutions described in the above embodiments, or equivalent replacements can be made for some or all of the technical features. Such modifications or replacements do not cause the essence of the corresponding technical solutions to depart from the scope of the technical solutions of the embodiments of the present disclosure.

For ease of explanation, the above description has been made with reference to specific embodiments. However, the above exemplary discussion is not intended to be exhaustive or to limit the embodiments to the specific forms as disclosed above. Many modifications and variations are possible in light of the above teachings. The above embodiments are selected and described in order to better explain the principles and practical applications, so that those skilled in the art can better use the embodiments and the embodiments with various modifications suitable for specific use considerations.

What is claimed is:

1. A signal processing circuit, comprising: a pulse widening circuit and an address decoding circuit, wherein
the pulse widening circuit is configured to receive a command signal and an address signal, and to widen a pulse width of the address signal through the command signal, thereby generating a widened address signal; and
an input terminal of the address decoding circuit is coupled to an output terminal of the pulse widening circuit for receiving the widened address signal, so as to decode the widened address signal and generate a decoded address signal corresponding to the address signal.

2. The signal processing circuit according to claim 1, wherein the pulse widening circuit comprises a first flip-flop; and
an in-phase clock input terminal of the first flip-flop is configured to receive a widening control signal, the widening control signal being the command signal or an inverted signal of the command signal; a data input terminal of the first flip-flop is configured to receive the address signal; the first flip-flop is configured to widen the pulse width of the address signal under control of the widening control signal, generate the widened address signal, and output the widened address signal through an output terminal.

3. The signal processing circuit according to claim 2, wherein the pulse widening circuit further comprises an inverter and a transfer gate, wherein
an input terminal of the inverter is configured to receive the command signal, and an output terminal of the inverter is coupled to an inverted clock input terminal of the first flip-flop; and
an input terminal of the transfer gate is configured to receive the command signal, and an output terminal of the transfer gate is coupled to the in-phase clock input terminal of the first flip-flop.

4. The signal processing circuit according to claim 2, wherein the pulse widening circuit further comprises an inverter and a transfer gate, wherein
an input terminal of the inverter is configured to receive the command signal, and an output terminal of the inverter is coupled to the in-phase clock input terminal of the first flip-flop; and
an input terminal of the transfer gate is configured to receive the command signal, and an output terminal of the transfer gate is coupled to an inverted clock input terminal of the first flip-flop.

5. The signal processing circuit according to claim 1, further comprising: a pre-processing circuit, wherein
a first output terminal of the pre-processing circuit is coupled to an input terminal of the pulse widening circuit, the input terminal being configured to receive the command signal, and a second output terminal of the pre-processing circuit is coupled to an input terminal of the pulse widening circuit, the input terminal being configured to receive the address signal; the pre-processing circuit is configured to receive a command address signal to decode and amplify the command address signal to obtain the command signal and the address signal.

6. The signal processing circuit according to claim 5, further comprising: a synchronization circuit, wherein two input terminals of the synchronization circuit are respectively coupled to an output terminal of the address decoding circuit and the first output terminal of the pre-processing circuit for synchronizing the decoded address signal and the command signal.

7. The signal processing circuit according to claim 6, wherein the synchronization circuit comprises a second flip-flop; a data input terminal of the second flip-flop is coupled to the output terminal of the address decoding circuit, and a clock input terminal of the second flip-flop is coupled to the first output terminal of the pre-processing circuit.

8. The signal processing circuit according to claim 6, further comprising: a delay circuit, wherein an input terminal of the delay circuit is coupled to the first output terminal of the pre-processing circuit, and an output terminal of the delay circuit is coupled to an input terminal of the synchronization circuit for outputting the command signal after being delayed to the synchronization circuit, so as to match delays introduced by the pulse widening circuit and the address decoding circuit.

9. The signal processing circuit according to claim 1, wherein the address signal comprises at least one of the following: a memory bank group address signal and a memory bank address signal; the command signal comprises at least one of the following: a pre-charge command signal, a refresh command signal, and a refresh management command signal.

10. A memory, comprising the signal processing circuit according to claim 1.
